(19) United States
(12) Patent Application Publication
(10) Pub. No.: US 2009/0106634 A1
(43) Pub. Date: Apr. 23, 2009

(54) ERROR DETECTING AND CORRECTING CIRCUIT USING CHIEN SEARCH, SEMICONDUCTOR MEMORY CONTROLLER INCLUDING ERROR DETECTING AND CORRECTING CIRCUIT, SEMICONDUCTOR MEMORY SYSTEM INCLUDING ERROR DETECTING AND CORRECTING CIRCUIT, AND ERROR DETECTING AND CORRECTING METHOD USING CHIEN SEARCH

(75) Inventor: Hiroaki MURAOKA, Kanagawa (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/245,063

(22) Filed: Oct. 3, 2008

(30) Foreign Application Priority Data
Oct. 18, 2007 (JP) 2007-271631

(51) Int. Cl. H03M 13/15; G06F 11/10

(52) U.S. Cl. 714/785; 714/E11.032

(57) ABSTRACT

An error detecting and correcting circuit is provided with a syndrome calculating circuit calculating a syndrome of an inputted data sequence including an error correcting code, a polynomial deriving circuit deriving an error location polynomial, a Chien searching circuit obtaining a location of error data of the data sequence, and an error correcting circuit correcting an error of the data, and every time the Chien searching circuit specifies the location of error data, the error correcting circuit immediately corrects the error of the data at the error location, and outputs the corrected data to an external circuit, thereby the error can be efficiently detected and corrected.

### CROSS REFERENCE TO RELATED APPLICATION

This application claims the benefit of Japanese Application No. 2007-271631 filed in Japan on Oct. 18, 2007; the contents of which are incorporated herein by this reference.

### BACKGROUND OF THE INVENTION

1. Field of the Invention

The present invention relates to an error detecting and correcting circuit using Chien search for correcting and decoding an error of received data, a semiconductor memory controller including the error detecting and correcting circuit, a semiconductor memory system including the error detecting and correcting circuit, and an error detecting and correcting method for the received data, and particularly, to the error detecting and correcting circuit using the Chien search, and the like.

2. Description of the Related Art

An error detecting and correcting technique is used in a variety of fields such as a data communication or a storage device in which an error may be induced because of a variety of reasons such as a noise and a damage of the storage device in a data-transmitting process, or a data-storing or a data-regenerating process.

For example, in a semiconductor memory device using a NAND-type flash memory, which is a rewritable storage device, as the number of rewrite times is increased, the error rate tends to increase. Particularly, in the NAND-type flash memory, as the capacity is increased, that is, as a circuit is micronized further, the error rate tends to increase. Thus, Japanese Patent Application Laid-Open Publication No. 2007-193910 describes that an error correcting code generating circuit and an error detecting and correcting circuit which execute a specific process are mounted in a flash memory chip, or a semiconductor memory controller controlling the flash memory chip.

The error detecting and correcting circuit is a circuit for detecting and correcting an error of a data sequence in which an error correcting code, such as the BCH (Bose-Chaudhuri-Hocquenghem) code or the Reed Solomon (RS) code which is a liner block code of the BCH code, is added by the error correcting code generating circuit before the data sequence is stored. When the stored data is read, and when the data sequence, to which the error correcting code is added, is inputted, the error detecting and correcting circuit detects and corrects an error of the inputted data sequence. The number of pieces of error data of error-correctable data depends on the added error correcting code; therefore, in the data sequence to which the t-tuple error correcting code is added, t pieces of error data can be corrected. That is, in the data sequence to which the t-tuple error BCH code is added, t bits of error data can be corrected, and in the data sequence to which the t-tuple error Reed Solomon code is added, in which one symbol corresponds to one byte, t bytes of error data can be corrected.

Each of the BCH code and the Reed Solomon code is a code configured by using a primitive polynomial on the Galois field and the characteristic of a root of the primitive polynomial. However, the difference between the BCH code and the Reed Solomon code is as follow: in the BCH code, data is treated by one bit, and the error correcting code is also generated by one bit, but on the other hand, in the Reed Solomon code, data is, for example, treated by eight bits, that is, one byte, and the error correcting code is also generated by one byte. In the Reed Solomon code in which the data and the error correcting code are expressed by byte, when the code is communicated and is regenerated, and this code is error-corrected to be decoded, the process is also executed by byte. Thus, since the date error is recognized by byte, the Reed Solomon code is suitable to such a case that a plurality of errors are highly-possibly induced by byte.

In the error detecting and correcting circuit, the data sequence including the BCH code or the Reed Solomon code is processed in the following order:

(1) a step for confirming the existence of an error;

(2) a step for calculating the number of errors (an error location polynomial deriving step);

(3) a step for calculating an error location; and

(4) a step for correcting the error.

In the step for calculating an error location, the Chien searching method is adopted. In the Chien searching method, all the possible values, for example 0 to M are sequentially substituted to a parameter X of the N-degree error location polynomial, and it is searched whether or not the error location polynomial is satisfied by the substituted value. Here, the M corresponds to the final bit location or the final byte location of the data sequence. When all of the N solutions are specified, that is, when all the locations of the N errors are specified, all the pieces of the error data are collectively corrected, and the corrected received data sequence is outputted.

Thus, when the error location is the final part of the received data sequence, in other words, the error location corresponds to a final value substituted in the Chien searching, after the final value is substituted in the Chien searching, the data is first corrected and is outputted. Thus, a time is spent until the data is outputted. In addition, since a capacity and a rate of a transfer bus of an output interface are limited, a large amount of data cannot be collectively outputted. Thus, a time may be also spent to output the error-corrected data.

As described above, the efficiency has been low in the hereto known error detecting and correcting circuit, the semiconductor memory controller including the error detecting and correcting circuit, and the error detecting and correcting method.

### SUMMARY OF THE INVENTION

An error detecting and correcting circuit, which is an aspect of the present invention, includes:

a syndrome calculating circuit configured to calculate a syndrome of a data sequence including an error correcting code;

a polynomial deriving circuit configured to derive an error location polynomial based on the syndrome;

an error correcting circuit configured to immediately correct an error of data including the error to output the corrected data to an external circuit; and

a Chien searching circuit configured to Chien search based on the error location polynomial, and, when it is determined that an error is not included in data at a location of the data sequence, immediately output the data to the external circuit and, when it is determined that an error is included in data at a location of the data sequence, immediately output the data including the error to the error correcting circuit.

A semiconductor memory controller, which is another aspect of the present invention, is provided with the error detecting and correcting circuit, the error detecting and correcting circuit includes:

a syndrome calculating circuit configured to calculate a syndrome of a data sequence including an error correcting code;

a polynomial deriving circuit configured to derive an error location polynomial generated based on the syndrome;

an error correcting circuit configured to immediately correct an error of data including the error to output the corrected data to the external circuit; and

a Chien searching circuit configured to Chien search based on the error location polynomial, and, when it is determined that an error is not included in data at a location of the data sequence, immediately output the data to the external circuit and, when it is determined that an error is included in data at a location of the data sequence, immediately output the data including the error to the error correcting circuit.

A semiconductor memory system, which is another aspect of the present invention, is provided with;

a host device; and

a semiconductor memory device, the semiconductor memory device including:

an error correcting code generating circuit configured to generate the error correcting code of the data sequence inputted from the host device, and provide the generated error correcting code to the data sequence;

a memory array configured to store the data sequence provided with the error correcting code;

a syndrome calculating circuit configured to calculate a syndrome of the data sequence including the error correcting code;

a polynomial deriving circuit configured to derive an error location polynomial based on the syndrome;

an error correcting circuit configured to immediately correct an error of data including the error to output the corrected data to the external circuit; and

a Chien searching circuit configured to Chien search based on the error location polynomial, and, when it is determined that an error is not included in data at a location of the data sequence, immediately output the data to the host device, and when it is determined that an error is included in data at a location of the data sequence, immediately output the data including the error to the error correcting circuit.

An error detecting and correcting method, which is another aspect of the present invention, includes:

a syndrome calculating step of calculating a syndrome of a data sequence including an error correcting code;

a polynomial deriving step of deriving an error location polynomial based on the syndrome;

a Chien searching step of Chien searching based on the error location polynomial, and, when it is determined that an error is not included in data at a location of the data sequence, immediately outputting the data to the external circuit and, when it is determined that an error is included in data at a location of the data sequence, immediately outputting the data including the error to an error correcting circuit; and

an error correcting step of immediately correcting the error of the data including the error, the data being determined at the Chien searching step to include the error, to output the corrected data to the external circuit.

### BRIEF DESCRIPTION OF THE DRAWINGS

FIG. 1 is a configuration diagram for describing a configuration of a semiconductor memory system according to a first embodiment;

FIG. 2 is a flowchart for describing a process flow of an error detecting and correcting circuit of the first embodiment;

FIG. 3 is a flowchart for describing a process flow of the error detecting and correcting circuit of a second embodiment;

FIG. 4 is a flowchart for describing a process flow of the error detecting and correcting circuit of the second embodiment, and the whole flowchart is a flowchart for describing a process flow of the hereto known error detecting and correcting circuit; and

FIG. 5 is a flowchart for describing a process flow of an error detecting and correcting circuit of a third embodiment.

### DETAILED DESCRIPTION OF THE PREFERRED EMBODIMENTS

Embodiments of the present invention will be described below referring to the drawings.

### First Embodiment

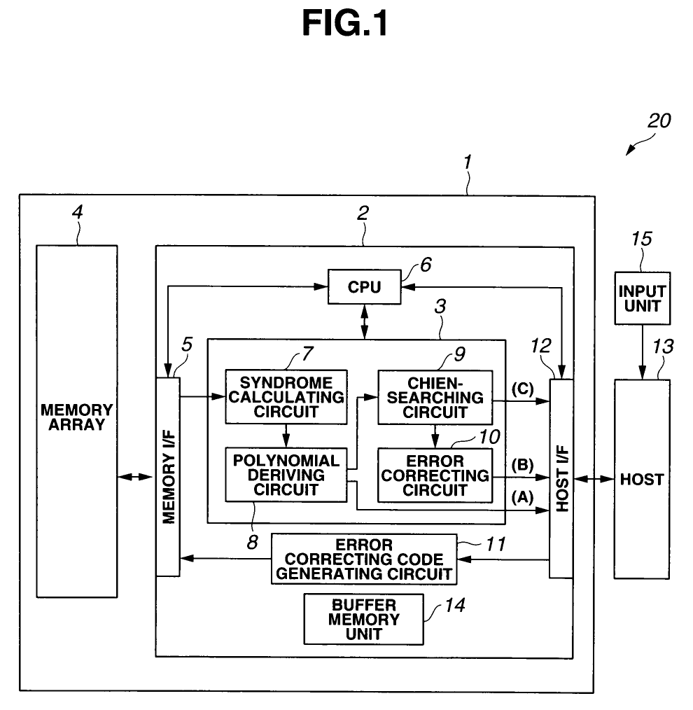

FIG. 1 is a configuration diagram illustrating a configuration of a semiconductor memory device 1 according to a first embodiment of the present invention. A semiconductor memory system 20 includes: a host device 13 such as a personal computer or a digital camera; and the semiconductor memory device 1 which stores data received from the host device 13 and transmits the stored data to the host device 13, which is, for example, a NAND-type flash memory device.

The semiconductor memory device 1 is configured with: a memory array 4; and a semiconductor memory controller 2.

The semiconductor memory controller 2 is controlled by a CPU 6 to transmit and receive data to and from the host device 13 through a host interface (I/F) 12, and to transmit and receive data to and from the memory array 4 through a memory interface 5. An error correcting code generating circuit 11 generates, for example, the BCH code or the Reed Solomon code from a data sequence configured with a predetermined unit of data from the host device 13, and adds an error correcting code to a redundant area. An error detecting and correcting circuit 3 includes: a syndrome calculating circuit 7 calculating a syndrome; a polynomial deriving circuit 8 deriving an error location polynomial; a Chien searching circuit 9 searching an error location; and an error correcting circuit 10 corrected a specified error. Such circuits are used in the above order to process the data sequence, added with the error correcting code, from the memory array 4.

That is, data, which is received from the host device 13, or the like outside the semiconductor memory device 1 to the semiconductor memory device 1, is added by the error correcting code generating circuit 11 with the error correcting code by a predetermined data sequence unit, and is stored in the memory array 4 through the memory interface (I/F) 5.

The data stored in the memory array 4 is received by the semiconductor memory controller 2 through the memory interface 5, the error is detected and corrected in the error detecting and correcting circuit 3 by the predetermined data sequence unit, and the corrected data is outputted to the host device 13 through the host interface 12 which is an external circuit of the error detecting and correcting circuit 3.

In the error detecting and correcting circuit 3, the syndrome of the data sequence is first calculated in the syndrome calculating circuit 7. When a calculated value of the syndrome is “zero”, it means that the number N of pieces of error data is “zero”, and because it is not necessary to correct the error, the data sequence is outputted following a path (A) of FIG. 1 to the host device 13 through the host interface 12 which is the external circuit of the error detecting and correcting circuit 3. When the calculated value of the syndrome is not “zero”, the error location polynomial is derived based on the calculated syndrome in the polynomial deriving circuit 8. Here, when coefficients of the error location polynomial are expressed by the N-degree polynomial, it means that the data sequence includes N pieces of the error data.

When N pieces of errors are found by deriving the error location polynomial, in the following step, the locations of the error data in the data sequence are sequentially specified in the Chien searching circuit 9. In the Chien searching circuit 9, the existence of the error is sequentially specified in the order of the location of the data. In the error detecting and correcting circuit 3 of the present embodiment, the data, whose location is determined not to include an error, is outputted following a path (C) of FIG. 1 to the host device 13 through the host interface 12 which is the external circuit of the error detecting and correcting circuit 3 before the existence of the error of the data at the next location is determined. On the other hand, in the Chien searching circuit 9, for the data of the error location, which is specified to include the error, the error is corrected in the error correcting circuit 10, and the corrected data is outputted following a path (B) of FIG. 1 to the host device 13 through the host interface 12 which is the external circuit of the error detecting and correcting circuit 3. That is, the error detecting and correcting circuit 3 of the present embodiment executes a process which is absolutely different from that of the hereto known error detecting and correcting circuit in which all the data of the data sequence is collectively corrected and outputted after all the error locations are specified in the Chien searching.

Meanwhile, in the error correction by the error correcting circuit 10, specifically, in the case of the data, whose unit is a bit, and which includes the BCH code, the data is bit-inverted, and in the case of the data, whose unit is a byte, and which includes the Reed Solomon code, the corrected eight-bit data is calculated by further using simultaneous linear equations.

The error detecting and correcting circuit 3 or the semiconductor memory controller 2 may include a buffer memory unit 14 which is a memory circuit. The buffer memory unit 14 is a memory temporarily storing data, and the like.

In the error detecting and correcting circuit 3 including the buffer memory unit 14, the data which is determined in the Chien searching circuit 9 not to include an error, or the data whose error is corrected in the error correcting circuit 10 is immediately outputted to the external circuit by each of the data unit by unit, for example, one bit or one byte; however, the outputted data may not be immediately transmitted to the host device 13. That is, by adjusting with the host interface 12, a plurality of pieces of the data, whose amount is less than a bus capacity corresponding to a transmission rate of the host interface 12, can be also collectively transmitted. For example, if the bus capacity, in other words, a bus width of the host interface 12 is eight bits, the data whose error is corrected or the data not including the error is sequentially stored in the buffer memory unit 14, and when the eight bits of data is stored in the buffer memory unit 14, the eight bits of data can be also collectively transmitted to the host device 13.

Meanwhile, the semiconductor memory system 20 may be a so-called embedded memory system in which the semiconductor memory device 1 and the host device 13 are combined, and the semiconductor memory device 1 cannot be removed from the host device 13.

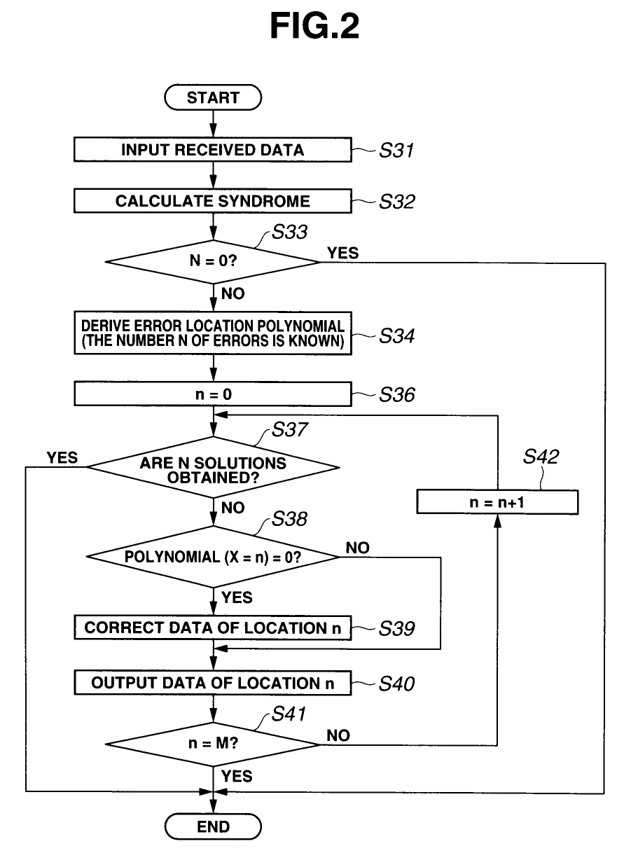

Next, a process flow of the error detecting and correcting circuit 3 of the first embodiment will be described in more detail by using FIG. 2. FIG. 2 is a flowchart for describing the process flow of the error detecting and correcting circuit 3 of the first embodiment.

The data stored in the memory array 4 is inputted as a data sequence in the semiconductor memory controller 2 through the memory interface 5 (step S31). The syndrome is calculated from the data sequence in the syndrome calculating circuit 7 (step S32: syndrome calculating step). When the calculated value of the syndrome is “zero”, it means that the number N of pieces of error data is “zero”, the determination at step S33 is Yes, and the data sequence is immediately transmitted following the path (A) of FIG. 1 to the host device 13 through the host interface 12 which is the external circuit of the error detecting and correcting circuit 3. When the calculated value of the syndrome is not “zero”, the determination at step S33 is No, and next, the error location polynomial is derived based on the syndrome in the polynomial deriving circuit 8 (step S34: polynomial deriving step). Here, the error location polynomial is, for example, indicated by the following formula.

a_{N}X^{N}+a_{N-1}X^{N-1}+ . . . +a₂X²+a₁X¹+a₀=0

The degree N of the error location polynomial indicates that the data sequence includes N pieces of the error data, and a value of X satisfying the error location polynomial indicates the location of the error bit or the error byte.

In the following step, the error location is specified by the Chien searching in the Chien searching circuit 9.

In the Chien searching, it is checked whether or not the error location polynomial is satisfied by substituting all the assumable values to X of the error location polynomial. Thus, “0” is set to n, which is substituted to X, as an initial value (step S36). It is determined whether or not the error location polynomial is satisfied by substituting n to X (step S38: Chien searching step). When the substituted n does not satisfy the error location polynomial, it means that the data at the location n does not include the error. Thus, the determination is No at step S38.

In the error detecting and correcting circuit 3 of the present embodiment, the data at the location n is immediately outputted at step S40 to the external circuit through the path illustrated by (C) of FIG. 1 without waiting for a result of the determination for the existence of the error of all the M pieces of data of the data sequence, and also, a result of the determination for the existence of the error of the data at the following location n+1.

By contraries, at step S38, when the substituted n satisfies the error location polynomial, it means that the data at the location n includes the error. That is, the determination is Yes at step S38. In such a case, the data at the location n is also immediately outputted to the error correcting circuit 10 without waiting for a result of the determination for the existence of the error in all the data, and at step S39 (error correcting step), the error of the data at the location n is corrected by the error correcting circuit 10, and the corrected data at the location n is outputted at step S40 to the external circuit through the path illustrated by (B) of FIG. 1.

Next, until all the N error locations in the data sequence are specified at step S37, or until n to be substituted to X becomes M, which is the maximum value of n, at step S41, n is incremented by one at step S42.

In the error detecting and correcting circuit 3 of the present embodiment, every time it is confirmed in the Chien searching circuit 9 that the data at a location of the received data sequence does not includes an error, the data, whose location is confirmed not to include the error, is immediately outputted to the external circuit.

In the error detecting and correcting circuit 3 of the present embodiment, every time the Chien searching circuit 9 specifies an error location, the error correcting circuit 10 corrects only an error at the specified error location to immediately output the corrected data to the external circuit. Thus, the error detecting and correcting circuit 3 of the present embodiment can execute the more efficient error correction as compared with the error detecting and correcting circuit in which, after all the errors of the data sequence including the M pieces of data are corrected, the M pieces of data are collectively outputted.

That is, in the error detecting and correcting circuit 3 of the present embodiment, the processed data is sequentially outputted to the external circuit without waiting for the termination of the Chien searching up to the received data at the location M; therefore, the outputting operation is rarely influenced by the restriction for the capacity and the rate of the transfer bus of the output interface. The host device 13 does not need to wait for the data, in which all the errors are corrected, to be outputted, and can sequentially process the outputted data.

Here, in the data outputted from the error detecting and correcting circuit 3 of the present embodiment to the external circuit, in the BCH code, the data is processed by a bit, and in the Reed Solomon code, the data is processed by a symbol. While the data outputted from the conventional error detecting and correcting circuit is the data sequence including M bits or M bytes, a unit of the data outputted from the error detecting and correcting circuit 3 of the present embodiment to the external circuit is at minimum one bit or, for example, one symbol of one byte. Since the unit is extremely small, the data can be efficiently outputted to the host interface 12 and the host device 13 which are the external circuits.

As described above, in the semiconductor memory controller 2 including the error detecting and correcting circuit 3 of the present embodiment, since the efficiency of the error detecting and correcting circuit 3 is high, a wait time and a load for the host interface 12 and the host device 13 are small. In addition, the error correction efficiency is high in the error correcting method of the present embodiment.

In the semiconductor memory system 20 including the semiconductor memory controller 2 including the error detecting and correcting circuit 3 of the present embodiment, since the efficiency of the error detecting and correcting circuit 3 is high, the wait time and the load for the host interface 12 and the host device 13 are small, and the error correction efficiency is high.

Meanwhile, the number M of pieces of the data processed in one unit of the error correcting code, strictly M+1, in other words, the number of pieces of the data in the data sequence depends on a type of a system, but is frequently around 250 to 16000.

### Second Embodiment

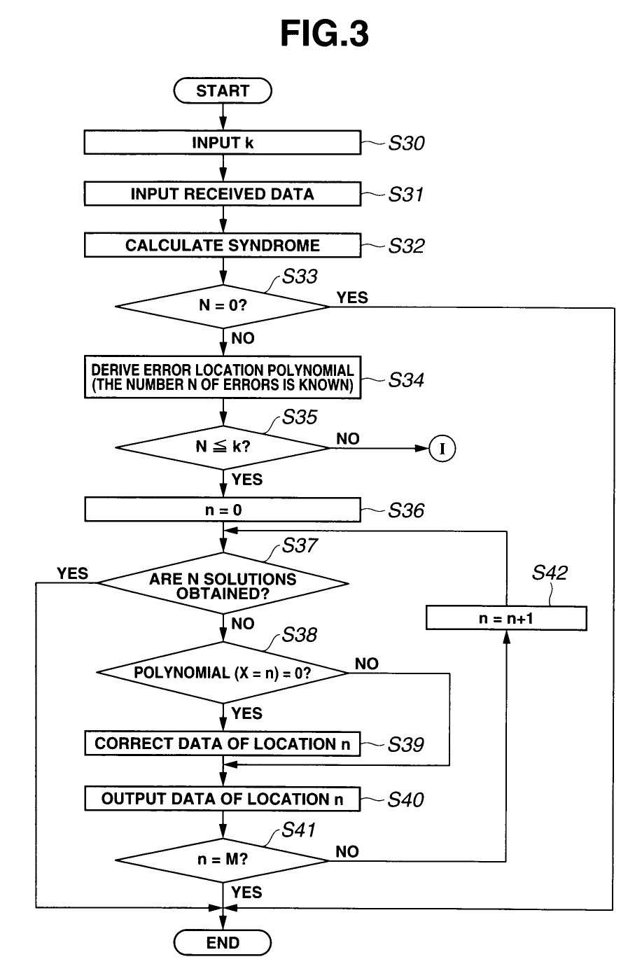

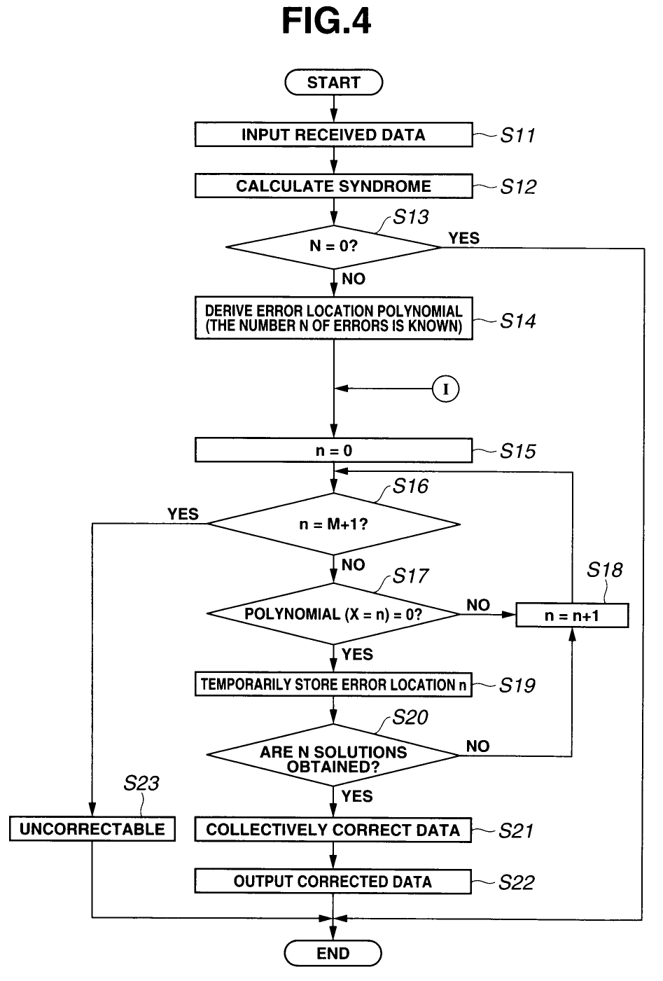

Next a process flow of the error detecting and correcting circuit 3 of a second embodiment will be described by using FIG. 3 and FIG. 4. FIG. 3 and FIG. 4 are flowcharts for describing the process flow of the error detecting and correcting circuit 3 of the present embodiment. A basic configuration of the error detecting and correcting circuit 3, and the like of the present embodiment is the same as that of the first embodiment illustrated in FIG. 1.

The flowchart illustrated in FIG. 3 for the error detecting and correcting circuit 3 of the present embodiment is similar to the flowchart illustrated in FIG. 2 for the error detecting and correcting circuit 3 of the first embodiment, so only the different process will be described.

The number of the errors is limited which can be corrected by the error detecting and correcting circuit 3. That is, the upper limit of the number t of the correctable errors is determined by the error correcting code provided in the error correcting code generating circuit 11. When the number N, detected at step S34, of the errors is large, for example, is equal to t, which is the number of the correctable errors, or (t−1), the errors may be not correctly corrected. That is, in the Chien searching, even if all the assumable values are substituted to X of the N-degree error location polynomial, N solution may be not obtained. In this case, even if the solutions of less than N are obtained during the Chien searching, such solutions cannot be trusted. Such a condition that the error cannot be correctly corrected cannot be determined until the final value M is substituted to X of the error location polynomial.

Thus, in the error detecting and correcting circuit 3 of the first embodiment, in which, when data at some location does not include an error, the data is outputted to the external circuit and, when data at another location includes an error, the error of the data is corrected, and the data is outputted to the external circuit, the incorrect data might be outputted to the external circuit, that is, the reliability of the system might be lowered.

In the process of the error detecting and correcting circuit 3 of the present embodiment, at the first step S30 (degree inputting step) illustrated in FIG. 3, the predetermined degree of the error location polynomial, that is, an upper limit permitted value k of the number of errors is, for example, inputted to the semiconductor memory device 1 through an input unit 15 of the host device 13. Meanwhile, it is not necessary to input the upper limit permitted value k, and the upper limit permitted value k may be inputted when the error detecting and correcting circuit 3 is generated, and may be a fixed value.

The upper limit permitted value k is determined from the reliability requested to the system under the consideration of the number t of the correctable errors. An integer of one or more is inputted to the upper limit permitted value k, and a smaller value is inputted in the system in which the higher reliability is required, by contraries, the value k may be the same as the number t of the correctable errors in the system in which the allowable range of the reliability is relatively wide. Meanwhile, experimentally, in the data sequence provided with the t-tuple error correcting code, in which the t errors can be corrected, when it is determined that the (t−1) or more errors are included, that is, when the degree of the error location polynomial is (t−1) or more, the errors may not be correctly corrected. By contraries, when the degree of the error location polynomial is less than (t−1) in the data sequence provided with the t-tuple error correcting code, that is, when the number of the errors is less than (t−1), it is very rare that the errors cannot be corrected.

At step S35, when the degree of the error location polynomial, that is, the number N of the detected errors is equal to or less than the upper limit permitted value k which is the determined degree, as illustrated in FIG. 3, the same process as that of the first embodiment illustrated in FIG. 2 is executed; however, when the number N of the detected errors is more than the upper limit permitted value k which is the determined degree, the process is executed from the flowchart (I) illustrated in FIG. 4.

When the number N of the detected errors is more than the upper limit permitted value k, the process is moved from step S35 of FIG. 3 to (I), that is, step S15 of FIG. 4. In the process, illustrated in FIG. 4, of the error detecting and correcting circuit 3, when the error location is specified at step S17, such an error location and all the data are temporarily stored in a memory not-illustrated in FIG. 1 (step S19). Next, when all the N error locations are specified (step S20), all the data corresponding to the N error locations are collectively corrected (step S21), and the data sequence configured with all the M pieces of data including the corrected data corresponding to the N error locations is collectively outputted (step S22). Meanwhile, the whole flowchart (from step S11) illustrated in FIG. 4 is the hereto known error detecting and correcting method using the Chien searching.

On the other hand, at step S 16 of FIG. 4, when the N solutions cannot be obtained even if all the assumable values, that is, “0” to M are substituted to X, it is determined that the error cannot be corrected by the error detecting and correcting circuit 3 (step S23). This is because the N+1 or more errors are included in the data sequence provided with the error correcting code which can correct at a maximum the N errors, and the already-obtained solution is not also assured to be correct.

In the error detecting and correcting circuit 3, or the like of the present embodiment, in addition to the advantageous effect obtained in the first embodiment, even when many errors are induced, the errors can be correctly corrected; therefore, the reliability of the output data is high. In addition, in the error detecting and correcting circuit 3, or the like of the present embodiment, when the number of the induced errors is small, the error can be efficiently corrected; therefore, the wait time and the load for the host interface 12 and the host device 13 are small.

In the semiconductor memory system 20 of the present embodiment, in addition to the advantageous effect included by the semiconductor memory system 20 of the first embodiment, even when many errors are induced, the errors can be correctly corrected; therefore, the reliability of the output data is high. In addition, in the semiconductor memory system 20 of the present embodiment, when the number of the induced errors is small, the errors can be efficiently corrected; therefore, the process efficiency is high.

### Third Embodiment

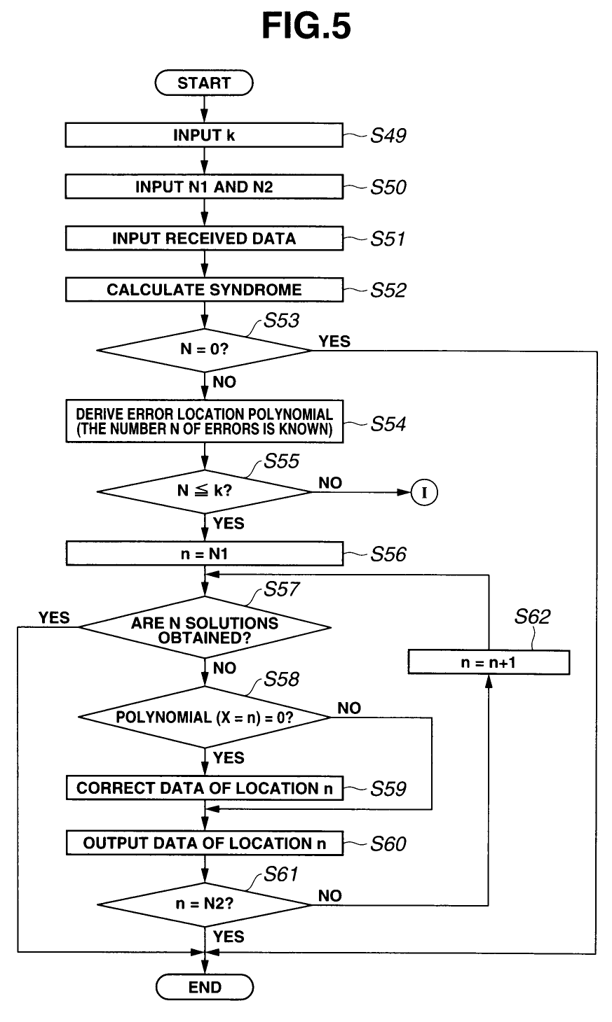

Next, a process flow of the error detecting and correcting circuit 3 of a third embodiment will be described by using FIG. 5. FIG. 5 is a flowchart for describing the process flow of the error detecting and correcting circuit 3 of the present embodiment. A basic configuration of the error detecting and correcting circuit 3, and the like of the present embodiment is the same as that of the first embodiment illustrated in FIG. 1.

The data sequence stored in the memory array 4 is provided with the error correcting code as a group of M pieces of data. Thus, in the hereto known error detecting and correcting circuit, even when only a part of the M pieces of data are necessary, the data is not outputted until it is completed to correct all the errors for the M pieces of data. For example, even when one piece of the data at the beginning location is necessary, the data is not outputted to the external circuit until it is completed to correct all the errors for the M pieces of data. Thus, in the hereto known error detecting and correcting circuit, the efficiency for correcting the error may have been low.

On the other hand, in the error detecting and correcting circuit 3 of the present embodiment, the error is corrected for the data in a range previously designated in the data sequence configured with the M pieces of data, and only the corresponding data is outputted to the external circuit. That is, when only a part of the data sequence, such as an attribute flag, is necessary, the error is corrected for only such a necessary data, and only the corrected data can be quickly outputted to the external circuit.

The flowchart, illustrated in FIG. 5, of the error detecting and correcting circuit 3 of the present embodiment is similar to the flowchart, illustrated in FIG. 3, of the error detecting and correcting circuit 3 of the second embodiment, so only the different process will be described.

As illustrated in FIG. 5, in the process of the error detecting and correcting circuit 3 of the present embodiment, like the error detecting and correcting circuit 3 of the second embodiment, at the first step S49, the predetermined degree of the error location polynomial, that is, the upper limit permitted value k of the number of errors is, for example, inputted to the semiconductor memory device 1 through the input unit 15 of the host device 13.

Meanwhile, at step S55, when the number N of the detected errors is more than the upper limit permitted value k, the process is executed from the flowchart (I) illustrated in FIG. 4. This is because when the number N of the detected errors, that is, the degree of the error location polynomial, is more than the upper limit permitted value k, and even when the Chien searching circuit 9 determines that the data at a certain location does not include an error, it cannot be experimentally determined whether or not the determination by the Chien searching circuit 9 is correct until the errors at all the locations are specified.

In the process of the error detecting and correcting circuit 3 of the present embodiment, at step S50, a predetermined range in which the error is corrected, that is, N1 and N2 are, for example, inputted to the semiconductor memory device 1 through the input unit 15 of the host device 13 (range input step). The N1 and N2 are integers of “0” or more, and M or less, which is the number of pieces of all the data, and correspond to locations including the desired data to be outputted.

Next, at step S56, N1 is set as an initial value of n which is substituted to X of the error location polynomial for the Chien searching. Next, the Chien searching circuit 9 executes the Chien searching until n becomes N2 at step S61.

In the Chien searching circuit 9 of the error detecting and correcting circuit 3 of the present embodiment, only the data in the necessary range is searched. Thus, in addition to the advantageous effect obtained by the error detecting and correcting circuits 3, and the like of the first embodiment and the second embodiment, in the error detecting and correcting circuit 3, and the like of the present embodiment, the error can be more efficiently corrected; therefore, the wait time and the load for the host interface 12 and the host device 13 are small.

In addition to the advantageous effect included by the semiconductor memory systems 20 of the first embodiment and the second embodiment, in the semiconductor memory system 20 of the present embodiment, the error can be more efficiently corrected; therefore, the process efficiency is high.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. An error detecting and correcting circuit, comprising:
a syndrome calculating circuit configured to calculate a syndrome of a data sequence including an error correcting code;
a polynomial deriving circuit configured to derive an error location polynomial based on the syndrome;
an error correcting circuit configured to immediately correct an error of data including the error to output the corrected data to an external circuit; and
a Chien searching circuit configured to Chien search based on the error location polynomial, and, when it is determined that an error is not included in data at a location of the data sequence, immediately output the data to the external circuit and, when it is determined that an error is included in data at a location of the data sequence, immediately output the data including the error to the error correcting circuit.

2. The error detecting and correcting circuit according to claim 1,
wherein, when a degree of the error location polynomial is more than a predetermined degree, after the errors of all the data of the data sequence are corrected, the Chien searching circuit outputs the data by a unit of the data sequence to the external circuit.

3. The error detecting and correcting circuit according to claim 1,
wherein the Chien searching circuit determines only an error location in a predetermined range of the data sequence.

4. A semiconductor memory controller, comprising:
an error detecting and correcting circuit, the error detecting and correcting circuit including:
a syndrome calculating circuit configured to calculate a syndrome of a data sequence including an error correcting code;
a polynomial deriving circuit configured to derive an error location polynomial based on the syndrome;
an error correcting circuit configured to immediately correct an error of data including the error to output the corrected data to an external circuit; and
a Chien searching circuit configured to Chien search based on the error location polynomial, and, when it is determined that an error is not included in data at a location of the data sequence, immediately output the data to the external circuit and, when it is determined that an error is included in data at a location of the data sequence, immediately output the data including the error to the error correcting circuit.

5. The semiconductor memory controller according to claim 4,
wherein, when a degree of the error location polynomial is more than a predetermined degree, after the errors of all the data of the data sequence are corrected, the Chien searching circuit outputs the data by a unit of the data sequence to the external circuit.

6. The semiconductor memory controller according to claim 4,
wherein the Chien searching circuit determines only an error location in a predetermined range of the data sequence.

7. A semiconductor memory system, comprising:
a host device; and
a semiconductor memory device, the semiconductor memory device including:
an error correcting code generating circuit configured to generate an error correcting code of a data sequence inputted from the host device, and provide the generated error correcting code to the data sequence;
a memory array configured to store the data sequence provided with the error correcting code;
a syndrome calculating circuit configured to calculate a syndrome of the data sequence including the error correcting code;
a polynomial deriving circuit configured to derive an error location polynomial based on the syndrome;
an error correcting circuit configured to immediately correct an error of data including the error to output the corrected data to an external circuit; and
a Chien searching circuit configured to Chien search based on the error location polynomial, and, when it is determined that an error is not included in data at a location of the data sequence, immediately output the data to the host device, and when it is determined that an error is included in data at a location of the data sequence, immediately output the data including the error to the error correcting circuit.

8. The semiconductor memory system according to claim 7,
wherein, when a degree of the error location polynomial is more than a predetermined degree, after the errors of all the data of the data sequence are corrected, the Chien searching circuit outputs the data by a unit of the data sequence to the external circuit.

9. The semiconductor memory system according to claim 7,
wherein the Chien searching circuit determines only an error location in a predetermined range of the data sequence.

10. The semiconductor memory system according to claim 7,
wherein the semiconductor memory device is a NAND-type flash memory device.

11. The semiconductor memory system according to claim 7,
wherein the error correcting code is the BCH code or the Reed Solomon code.

12. The semiconductor memory system according to claim 7,
wherein the semiconductor memory device includes a buffer memory unit, and outputs the data sequence to the host device according to a data transfer rate between the host device and the semiconductor memory device.

13. An error detecting and correcting method, comprising:
calculating a syndrome of a data sequence including an error correcting code;
deriving an error location polynomial based on the syndrome;
Chien searching based on the error location polynomial, and, when it is determined that an error is not included in data at a location of the data sequence, immediately outputting the data to an external circuit and, when it is determined that an error is included in data at a location of the data sequence, immediately outputting the data including the error to an error correcting circuit; and
immediately correcting the error of the data including the error, the data being determined in the Chien searching to include the error, to output the corrected data to the external circuit.

14. The error detecting and correcting method according to claim 13, further comprising:
inputting a predetermined degree of the error location polynomial,
wherein, when the degree of the error location polynomial is more than the degree inputted in the inputting the predetermined degree, after the errors of all the data of the data sequence are corrected, the Chien searching outputs the data by a unit of the data sequence to the external circuit.

15. The error detecting and correcting method according to claim 13, further comprising:
inputting a predetermined range in which the error is detected and corrected,
wherein the Chien searching determines only an error location of the predetermined range of the data sequence.
